(19) United States
(12) Patent Application Publication
(10) Pub. No.: US 2005/0221870 A1
(43) Pub. Date: Oct. 6, 2005

(54) Method and circuit for determining a slow clock calibration factor

(75) Inventors: Janos Erdelyi, Dunakeszi (HU); Peter Onody, Budapest (HU)

Correspondence Address: GARDNER CARTON & DOUGLAS LLP;ATTN: PATENT DOCKET DEPT., 191 N. WACKER DRIVE, SUITE 3700, CHICAGO, IL, 60606, US

(73) Assignee: Integration Associates Inc., Mountain View, CA (US)

(21) Appl. No.: 10/819,056

(22) Filed: Apr. 6, 2004

(51) Int. Cl. H03M 1/38

(52) U.S. Cl. 455/574

(57) ABSTRACT

Shown is a method and circuit for determining a calibration factor between a fast, high accuracy clock signal and a slow, low accuracy clock signal, which can be realised with a minimum number of electronic units, and which obtains the calibration factor in a very short time, thus minimising power consumption of the circuit. The present invention operates by counting the number of cycles of a high accuracy clock signal during a single cycle of a low accuracy clock signal to obtain a first number representing the number of cycles counted and then successively summing the first number until a sum of the first numbers reaches a first predetermined value. The count of the number of summing operations required to reach the first predetermined value is then used to determine the calibration parameter, which is proportional to the number of summing operations.

### FIELD OF THE INVENTION

The invention relates to a method and circuit for determining a calibration parameter, where the calibration parameter is used to compensate for the variations of a low accuracy clock signal compared to a high accuracy clock signal.

### BACKGROUND OF THE INVENTION

Various electronic devices require a more or less exact and reliable clock signal. Such clock signals are typically generated by various types of oscillators, which deliver an alternating current (AC) signal on a fixed or tunable frequency. There are certain applications which require an accurate reference frequency. Particularly, wireless devices need accurate reference clock signals to generate a precise radio frequency (RF) local oscillator frequency and for maintaining an exact time base so that they are able to transmit between the transmitter and the receive at precise time intervals.

Moreover, an increasing number of wireless devices are designed to be operated by battery. These devices may be required to operate for a relatively long time, in some instances for at least a year. Examples of such devices are radio transmitters and receivers built into an external sensor and an indoor monitoring station, such as thermometer-weather station. In order to increase battery life, such devices are designed for reduced power consumption. The power consumption is sought to be reduced by sending the data from the transmitter at certain periods only. An exact time base is necessary for the synchronous time-keeping between the sender and the receiver, so that both units switch on and off simultaneously, and may communicate with each other in predetermined time slots. For example, if the duration of the active transmission time is negligible compared with the duration of the idle times between the time slots, the exact timing of these time slots can bring substantial savings in the duration of the transmission, which directly translates into longer battery life.

It is known in the art that high frequency crystal oscillators are generally much more accurate than resistor capacitor (RC) oscillators, and in most wireless devices, a high frequency crystal oscillator is present anyway, mostly for the purposes of the RF transmission. However, high frequency crystal oscillators have higher power consumption, even during those time periods when the device is actually not transmitting or receiving. Therefore, it has been proposed to install a slower clock signal source having a lower consumption, and to turn off the high frequency oscillators during idle periods, using the slow clock signal for reference purposes. It would be possible to use another crystal oscillator as a slow clock, but it is desired to avoid another crystal in the circuit. Instead, it is more feasible to implement the functions of the slow clock with an RC circuit, which is lower in cost and possible to integrate into a chip circuit. RC oscillators, however, are less accurate. It has also been proposed to calibrate periodically the slow clock to the high frequency clock, either automatically, after a predetermined sleep time has elapsed, or whenever a wake-up of the device is triggered by an external event.

U.S. Pat. No. 6,029,061 (Kohlschmidt) and No. 6,453,181 (Challa et al) disclose various power saving schemes for mobile phones, wherein a slow, but inaccurate sleep mode clock is calibrated to a higher frequency, accurate reference clock at certain intervals. Specifically, U.S. Pat. No. 6,029,061 discloses a method where the fast clock signal and the slow clock signal is used to increment or decrement two registers during a specified time period, and thereafter a timing relationship is established between the slow and the fast clock signal.

However, the method and implementing apparatus disclosed in U.S. Pat. No. 6,029,061 is realized in the context of a mobile phone, and requires the use of relatively complicated control circuits, such as a digital processor, to obtain the calibration factor. Such complicated circuitry is relatively expensive, and is itself power-consuming. Furthermore, the calibration process is relatively long, and requires multiple cycle times of the slow clock. This will not play a significant role in a mobile phone, which is expected to be switched on relatively often, and is also expected to be recharged regularly. However, this method is relatively expensive and inefficient if it needs to be realised in a cheap and low-power device, which is expected to run for a long time without external wake-ups, and where the majority of the automatically initiated wake-up times are only used for performing the calibration of the slow clock source.

A similarly complicated power saving scheme is disclosed in U.S. Pat. No. 6,453,181. This known method provides a very accurate calibration of the slow clock, but requires extensive calculating and controlling functions, the implementation of which is not feasible in simple and cheap wireless devices.

### SUMMARY OF THE INVENTION

In an embodiment of the present invention, there is provided a method for determining a calibration parameter, where the calibration parameter is used to compensate the variations of a low accuracy clock signal compared to a high accuracy clock signal. The method calls for:
counting the number of cycles of said high accuracy clock signal during a single cycle of the low accuracy clock signal, and obtaining a first number being equal to the counted number of cycles,
successively performing multiple summing operations with the first number, until the sum of the first numbers reaches a first predetermined value, and
counting the number of summing operations, the calibration parameter being proportional to the number of summing operations.

In another embodiment of the present invention, there is provided a circuit assembly for providing a calibrated clock signal in a sleep mode, using a high accuracy clock and a low accuracy clock which is periodically calibrated to the high accuracy clock when the high accuracy clock is in a wake-up mode. The circuit assembly includes a high accuracy clock source, a low accuracy clock source, and a calibration circuit for providing a calibration parameter, where the calibration parameter is used to compensate the variations of the frequency of the low accuracy clock signal compared to a high accuracy clock signal. The circuit assembly further includes a frequency calibration circuit for providing a calibrated clock signal from the low accuracy clock signal and the calibration parameter. The calibration circuit includes a first register for counting the number of clock cycles of the high accuracy clock during a clock cycle of the low accuracy clock, and for obtaining a first number. The calibration circuit further includes an accumulator for performing successive summing operations of the first number obtained from the first register, and a second register for counting the number of summing operations performed by the second register and obtaining a second number. The circuit assembly also includes a control circuit. The control circuit controls the counting operations of the first and second registers, and the summing operations of the accumulator. The control circuit also monitors the contents of the accumulator and indicates when the content of the accumulator reaches a predetermined value, and outputs the second number from the second register as the calibration parameter when the content of said accumulator reaches the predetermined value.

The disclosed method and circuit is capable of obtaining the calibration factor within a relatively short time and does not require sophisticated circuits, such as a number divider circuit. The calibration factor is obtained as an integer number, and may be fed directly into a frequency divider circuit.

### BRIEF DESCRIPTION OF DRAWINGS

The invention will be now described with reference to the enclosed drawings, where:

FIG. 1 is a functional block diagram illustrating one embodiment of a wake-up type circuit according to the present invention, providing a calibrated frequency output based on a periodically calibrated low accuracy clock,

FIG. 2 is a functional block diagram illustrating one embodiment of the calibration factor calculator circuit of the circuit assembly shown in FIG. 1.

### DETAILED DESCRIPTION OF THE INVENTION

The present invention is directed toward a method and circuit for determining a calibration factor between a fast, high accuracy clock signal and a slow, low accuracy clock signal, which can be realised with a minimum number of electronic units, and which obtains the calibration factor in a very short time, thus minimising power consumption of the circuit. Such a calibration circuit also makes it possible to take into account the process tolerances of the various circuit elements, so the complete calibration circuit may be integrated on a single chip, if necessary.

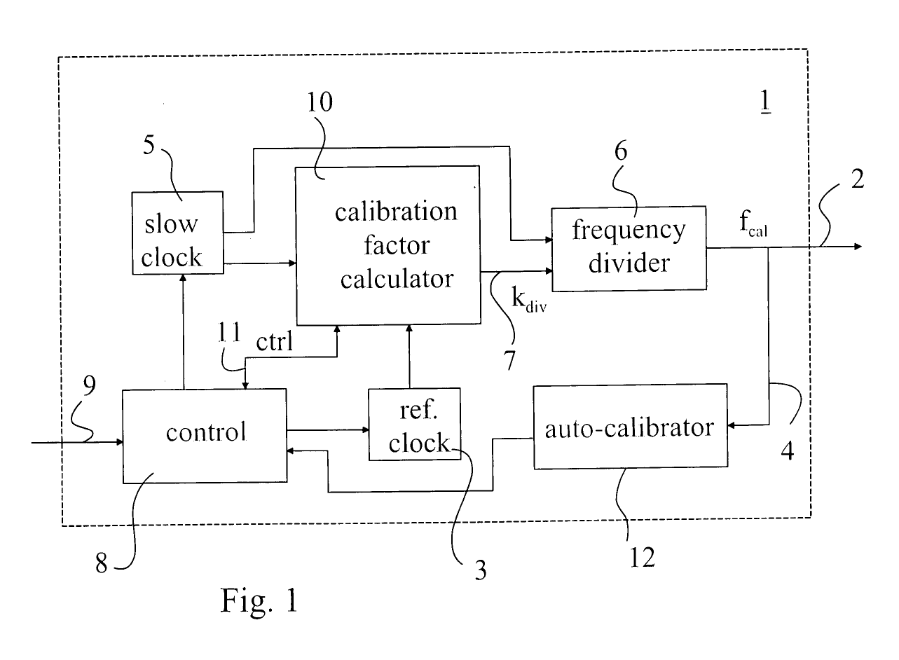

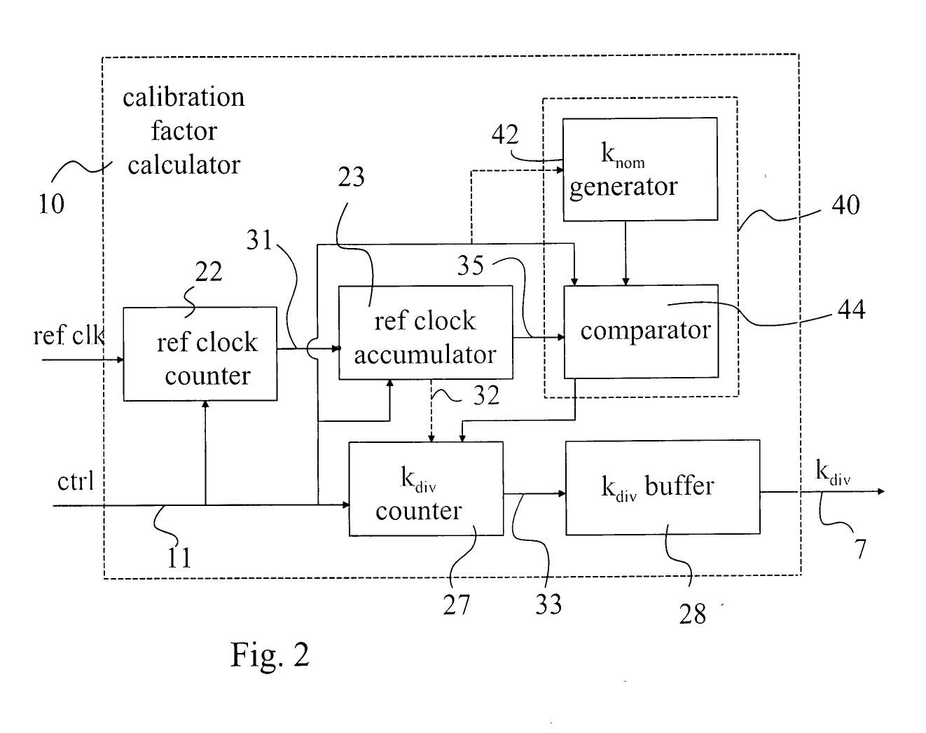

Referring now to FIGS. 1 and 2, there is shown an embodiment of the circuit assembly in accordance with the invention, in the form of a wake-up circuit 1, which may form part of an external device (not illustrated), such as a radio transmitter-receiver unit. The wake-up circuit 1 is capable of providing a calibrated frequency during certain modes of operation, typically when the external device or at least the wake-up circuit 1 itself is in a low power sleep mode. In this sleep mode, it is still necessary to maintain a relatively accurate time base, for example for a receiver unit, or for an auto-calibrator circuit 12. For this purpose, the wake-up circuit provides a calibrated frequency f_{cal}, delivered at an output line 2 or to the internal line 4 providing the input of the auto-calibrator circuit 12. This latter forms a separate circuitry within the wake up-circuit 1, which periodically tunes the calibrated frequency f_{cal} to a nominal output frequency fₙₒₘ, as will be explained in more detail below. The nominal output frequency fₙₒₘ may be considered as a nominal value of a sleep mode frequency of the wake-up circuit 1, because the wake-up circuit 1 generates the calibrated frequency f_{cal} at its output terminal when it is in either the sleep mode or a passive mode. The invention concerns a method and circuit for calibrating the calibrated frequency f_{cal} with relatively few components and in a relatively short time.

The wake-up circuit 1 includes a reference clock source 3, which in one embodiment, is a crystal oscillator. The reference clock source 3 provides a high accuracy clock that has a stable frequency and needs no calibration on its own. The high accuracy clock frequency f_{ref} of the reference clock source 3 is used to calibrate the slow clock source 5, which is a low accuracy clock. This means that the output frequency f_{slow} of the slow clock may vary due to various factors, such as temperature or process tolerances, and such variations need to be compensated in order to ensure proper functioning of the external device which relies on the slow clock signal. The slow clock source 5 in one embodiment, is realized as an RC oscillator.

The wake-up circuit 1 has a first mode (wake-up mode or active mode), wherein its reference clock source 3 and substantially all its component circuits are active. The wake-up circuit 1 also has a second mode (sleep mode or passive mode), in which it is partially shut off, particularly its power-consuming reference clock source 3. In the sleep mode, substantially only the slow clock source 5 is active, supplying a slow clock signal having the frequency f_{slow}, which, for example, may be approximately 50 kHz. The output frequency of the slow clock source 5 is fed into a frequency divider circuit 6, which divides the input frequency f_{slow} with a division factor k_{div}, and thereby produces an output frequency f_{cal}. The frequency divider 6 is of a type that has no fixed frequency division ratio, but performs the frequency division according to a division factor k_{div}, having an integer value and being received from an input line 7, which may be a 8-bit parallel bus. For example, such frequency divider circuits are known to those of ordinary skill in the art, and need not be explained in more detail.

As mentioned above, the slow clock frequency f_{slow} may vary. Therefore, in the present invention, the division factor k_{div}, is varied in order to obtain a more or less stable and calibrated output frequency f_{cal} on the output 2 or on the internal line 4. For this purpose, the wake-up circuit 1 relies on its high accuracy reference clock source 3 for periodically checking the frequency of its low accuracy slow clock source 5, when the reference clock source 3 is in an active mode, i. e. when the reference clock source 3 is switched on.

The wake-up circuit 1 has a calibration circuit 10, which generates a calibration parameter. In the present embodiment, the calibration parameter is the division factor k_{div}, which may be fed directly to the frequency divider circuit 6. Since the value of the division factor k_{div} is obtained by indirectly measuring the actual ratio between frequency f_{slow} of the slow clock and the frequency f_{ref} of the reference clock, the value of the division factor k_{div} reflects this ratio, and therefore the division factor k_{div} is suitable for calibrating the output frequency f_{cal} of the wake-up circuit 1.

The wake-up circuit 1 shown in FIG. 1 further comprises an auto calibrator circuit 12. The auto calibrator circuit 12 itself also requires a nominal frequency fₙₒₘ, which can be used as a reliable time base of the auto calibrator circuit 12, acting as the “alarm clock” of the wake-up circuit. In the shown embodiment, the calibrated output frequency f_{cal} of the wake-up circuit 1 is also tuned to this nominal frequency fₙₒₘ. More precisely, the calibration circuit 10 seeks to adjust the value of the division factor k_{div} so that the relation fₙₒₘ=f_{cal} is fulfilled.

The different units of the wake-up circuit 1 are controlled by a control circuit 8. This may be embodied by a digital processor, but more preferably it is a simple state machine-type circuit, where the few simple controlling functions of the control circuit 8, such as monitoring the states of, and the enabling, halting or resetting the other circuits are hardware implemented. As it will be apparent for a person skilled in the art, the control functions of the wake-up circuit 1 may be realized within a few logic gates.

As mentioned above, the calibrated output frequency f_{cal} is obtained by dividing a slow clock frequency f_{slow}. with the division factor k_{div}. Accordingly, the nominal frequency fₙₒₘ may be expressed as follows:

$${f}_{nom} = {f}_{cal} = \frac{{f}_{slow}}{{k}_{div}} \qquad ( I )$$

where k_{div}=k_{div}(f_{low}, f_{ref}), i. e. the division factor k_{div} is a function of the proportion between the (constant) reference frequency f_{ref} and the (variable) slow clock frequency f_{slow}, because the calibration of the nominal frequency fₙₒₘ relative to the slow clock frequency f_{slow} is based on the reference frequency f_{ref}, as mentioned above.

Let us assume that the reference frequency f_{ref} is used for obtaining the nominal frequency fₙₒₘ directly. Accordingly,

$${f}_{nom} = \frac{{f}_{ref}}{{k}_{nom}} \qquad ( II )$$

where kₙₒₘ is a constant, keeping in mind that both the nominal frequency fₙₒₘ and the reference frequency f_{ref} are considered as constants. Combining equations I and II and eliminating fₙₒₘ, we obtain

$$\frac{{k}_{div}}{{f}_{slow}} = \frac{{k}_{nom}}{{f}_{ref}} = T \qquad ( III )$$

where T is a time value, with the following physical meaning: kₙₒₘ number of cycles of a frequency f_{ref} will have the duration of T. Similarly, it also holds that k_{div} number of cycles of a frequency f_{slow} will have the duration of T, as it is apparent from the equation III. This may be again reformulated as the following statement: A frequency f_{slow} will have k_{div} number of cycles during a time interval T.

Using a similar approach, starting from equation (III), we may write

$${k}_{div} = \frac{{f}_{slow}}{{f}_{ref}} {k}_{nom} \qquad ( IV )$$

Further, introducing the variable factor m as the factor between the slow clock frequency f_{slow} and the reference frequency f_{ref}, expressed as f_{slow}=m f_{ref}, we obtain

$$\frac{{f}_{slow}}{{f}_{ref}} = \frac{1}{m} \qquad ( V )$$

Substituting Eq. IV into Eq. V, we obtain

$${k}_{div} = \frac{{k}_{nom}}{m} \qquad ( IV )$$

Eq. V may be also formulated as

$$\frac{m}{{f}_{ref}} = \frac{1}{{f}_{slow}} = {T}_{slow} \qquad ( V )$$

which, as explained above, has the following concrete physical meaning: T_{slow} is the cycle time of the slow clock frequency f_{slow}, i. e. during a time interval T_{slow} the slow clock frequency f_{slow} makes a single cycle. Similarly, during the time T_{slow} the reference frequency f_{ref} will have m number of cycles. Rearranging Eq. IV, we obtain
k_{div}·m=kₙₒₘ (VI)

Eq. VI is the basis for obtaining the frequency division factor k_{div} in a very simple manner, with the help of the measured value of m and the calculated value of kₙₒₘ. Namely, Eq. VI may be considered as stating: the value m must be repeated k_{div} times for arriving at the value kₙₒₘ. An embodiment of the method and apparatus of the invention is based on the practical implementation of this recognition.

A possible embodiment of the calibration circuit 10 is shown in FIG. 2, showing the functional units of the calibration circuit 10. There is a reference clock counter 22, which is substantially an incremental register, an accumulator circuit 23 in combination with a comparator 40, and a divisional factor counter 27, the latter again realised as a simple incremental register. In the embodiment shown in FIG. 2, the calibration circuit 10 also includes a divisional factor buffer 28, which is also a simple register.

The main function of the reference clock counter 22 is counting the number of clock cycles of the reference clock source 3 during a single clock cycle of the slow clock source 5. In this manner the reference clock counter 22 obtains the number m=f_{ref}/f_{slow}, as explained above. In fact, since the reference clock counter 22 only counts integers, the mᵢₙₜ=int(m) value is found by the reference clock counter 22.

Under the control of the control circuit 8, the accumulator 23 receives at its input the value of the reference clock counter 22 through line 31, where line 31 may be a multi-bit bus. The accumulator 23 performs successive summing operations with the value received on its input, in the sense that when enabled, the accumulator 23 successively adds the input value to the actually stored value in the accumulator 23, at every clock pulse. Such an accumulator may be realised in a simple manner as the combination of a register and an adder, where the output of the register is fed back to an input of the adder, while the other input of the adder is considered as the input of the accumulator.

The divisional factor counter 27 in the calibration circuit 10 is another incremental register. It may be connected to the accumulator 23 through a line 32, but this latter may be also omitted. The divisional factor counter 27 counts the number of summing operations performed by the accumulator 23, i. e. when the divisional factor counter 27 is enabled, at every clock pulse when the accumulator 23 performs a summing operation, the divisional factor counter 27 is incremented with the value of one. As mentioned above, it is not strictly necessary to connect the accumulator 23 and the divisional factor counter 27, but the control circuit 8 may simply issue a common enabling signal and a common clock to the accumulator 23 and the divisional factor counter 27.

The control circuit 8 is designed to monitor the content of the accumulator 23, and to indicate when the content of the accumulator 23 reaches a predetermined value. For this purpose, the calibration circuit 10 comprises the comparator 40, which receives one of its inputs from the accumulator 23 through line 35. In the shown embodiment, the comparator circuit 40 is designed to compare an integer value received from the accumulator 23 with the integer value int(kₙₒₘ), where kₙₒₘ=f_{ref}/fₙₒₘ, as defined by Eq. II above. In the following discussion, we will consider the kₙₒₘ=int(kₙₒₘ) simplification, taking into account that the high accuracy clock frequency f_{ref} is normally several magnitudes higher than the desired nominal output frequency fₙₒₘ, so the neglecting of the fractional value of kₙₒₘ involves a small error only. The comparator circuit 40 may be designed to compare a hardware implemented, fixed kₙₒₘ value with the contents of the accumulator 23, such as shown in FIG. 2, where the kₙₒₘ generator 42 and the comparator 44 together constitutes the comparator circuit 40. In this case the kₙₒₘ generator 42 is wired to output an integer, fixed kₙₒₘ value to the comparator 44 through the line 36. Instead of a general-purpose comparator (i. e. which is capable of comparing two arbitrary inputs) it is also possible to design the comparator 44 to compare only a wired, fixed kₙₒₘ value with a single arbitrary input value. In this case the fixed kₙₒₘ value is not fed to the comparator 44 from an external source, and the comparator 44 is itself designed for performing the comparison between an arbitrary input value and the predetermined fixed value. This solution may be designed with a few gates only, and it is preferable where the reference frequency f_{ref} of the high accuracy clock is known exactly, and the nominal output frequency fₙₒₘ need not be varied. For example, the high accuracy clock may run on a frequency of 2.5 MHz, and the desired nominal output frequency fₙₒₘ may be 2 kHz, resulting in a kₙₒₘ value of 1250.

Alternatively, the desired nominal output frequency fₙₒₘ may vary, if a variable value of kₙₒₘ is fed to the comparator 40 either directly from the control circuit 8, or from the kₙₒₘ generator 42, by controlling a kₙₒₘ value generating algorithm within the kₙₒₘ generator 42.

As mentioned above, the calibration circuit 10 also comprises a divisional factor buffer 28. Under the control of the control circuit 8, the divisional factor counter 27 may latch its content to the divisional factor buffer 28 through line 33. This latter maintains the latched value until resetting, or until another value is received from the divisional factor counter 27. The content of the divisional factor buffer 28 are output on line 7.

At the end of a calibration procedure explained further below, it is the content of the divisional factor buffer 28 which represents the sought value k_{div}, which may be output as the calibration parameter from the calibration circuit 10.

The circuit works as follows: Upon start-up of the circuit or after a reset, both the reference clock source 3 and the slow clock source 5 are turned on. The calibration process may allow some time for the clocks to reach their stable frequency. During periodic calibrations, when the wake-up circuit returns to the active mode from a sleep mode, the slow clock source 5 is continuously switched on, since it is the source of the output frequency f_{cal}, and therefore needs no settling time. For example, the reference frequency f_{ref} may be 2.5 MHz, while the slow clock frequency f_{slow} may settle for a value between 20-100 kHz, depending on process tolerances and ambient temperature. In the meanwhile, the reference clock counter 22, the accumulator 23 and the divisional factor counter 27 are reset to zero.

Under the control of the control circuit 8, which monitors the clock pulses from both the reference clock source 3 and the slow clock source 5, the reference clock counter 22 starts to count the clock pulses of the reference clock source 3, simultaneously with a clock pulse of the slow clock source 5, and continues the count until the next clock pulse of the slow clock source 5. In practice, this is simply realized by resetting the reference clock counter 22 to zero upon a slow clock pulse and clocking the reference clock counter 22 with the clock pulses of the reference clock source 3. Since the reference clock counter 22 is an incremental register, it will count the number of cycles of the high accuracy clock signal during a single cycle of the low accuracy clock signal. The counting of the reference clock pulses stops upon the next clock pulse of the slow clock. In this manner, between two clock pulses of the slow clock source 5 the reference clock counter 22 will obtain the variable factor m as defined by equations II and V. More properly, it will obtain the integer value mᵢₙₜ=int(f_{ref}/f_{slow}). For the following discussion, we will use the m=mᵢₙₜ approximation.

In the next step, simultaneously as the reference clock counter 22 stops the counting, its content, i. e. the variable factor m is fed through line 31 to the accumulator 23. For example, if the momentary value of f_{slow} is 50 kHz, the reference clock counter 22 will increment until m=50. This m value is then maintained in the reference clock counter 22, until reset to zero by the control circuit 8 in the next calibration process.

Having stopped the counting of the reference clocks counter 22, the control circuit 8 now enables the operation of the accumulator 23, which is also clocked with the reference frequency f_{ref}. At every clock pulse of the reference clock source 3, the content of the accumulator 23 is increased with the value of m. At the same time, the content of the accumulator 23 is fed to the comparator circuit 40, which indicates when the content of the accumulator 23 reaches or surpasses the kₙₒₘ input value of the comparator, either towards the control circuit 8 or towards the divisional factor counter 27. For example, assuming kₙₒₘ=1250 and m=50, after 1250:50=25 cycles of the reference clock source 3, the accumulator 23 will reach the value 1250.

Simultaneously with the accumulator 23, the control circuit 8 will also enable the operation of the divisional factor counter 27, which is also clocked to the reference clock source 3. The divisional factor counter 27 will increment with the value of one at every clock pulse. Having reached the predetermined value of kₙₒₘ, upon the signal from the comparator 40, the control circuit 8 will stop the counting of the divisional factor counter 27, which has in this manner calculated the number of summing operations performed by the accumulator 23, since the two units were enabled and subsequently stopped simultaneously. Accordingly, the divisional factor counter 27 has in fact calculated the result of the division kₙₒₘ/m=k_{div}, according to Eq. IV. More precisely, the divisional factor counter 27 now contains the integer value k_{div}=int(kₙₒₘ/m).

As is clear from the description above, the divisional factor counter 27 has, in this manner, directly obtained the desired calibration parameter for calibrating the slow clock frequency f_{slow}, e.g. the division factor k_{div}. This is now fed to the divisional factor buffer 28 under the control of the control circuit 8, where it is maintained for output to the frequency divider 6 until a new calibration procedure is performed and a new division factor k_{div} is obtained.

As is apparent to one of ordinary skill in the art, the calibration parameter may be obtained during less than two complete clocks cycles of the slow clock source 5. Thereafter, the control circuit may switch off the power-consuming reference clock source 3, and also many parts of the calibration circuit 10, with the exception of the divisional factor buffer 28. The slow clock source 5, and possibly the auto-calibration circuit 12 remain active.

The wake-up circuit 1 explained with reference to FIGS. 1 and 2 has a very simple structure, which may be realized with a few standard logic building blocks, which are easily integrated in a single chip.

It must be noted that maximum error of the proposed method of frequency calibration is less than 5%, when operating in the orders of magnitude as described above. This error results mainly from the truncation errors, which are due to the use of integers for the values of kₙₒₘ, m and k_{div}. The average truncation error may be partly compensated by modifying the value of kₙₒₘ slightly. For example, in the case of the specific values discussed above, instead of setting kₙₒₘ=1250, better results can be obtained by increasing the value to kₙₒₘ=1254 or kₙₒₘ=1255. This increase will take into account some of the losses made during the truncations, and also helps to offset asymmetries of the frequency error of the slow clock.

A new calibration procedure may be initiated in various situations. For example, an external signal, such as the pressing of a button may initiate the calibration procedure through the input line 9 of the control circuit 8. Typically, beside such external factors, the wake-up circuit will automatically initiate a calibration of the slow clock frequency, to take into account frequency drifts caused by temperature changes or the like. For this purpose, the auto-calibrator circuit 12 of the wake-up circuit 1 will regularly initiate a calibration, for example every 30 seconds. The auto-calibrator circuit 12 may be considered as an independent control circuit, which keeps time with an internal register clocked by the calibrated frequency f_{cal}, and detects automatically when the predetermined sleep time has elapsed. Such auto-calibrator circuits are known per se, and need not be discussed in more detail.

The invention is not limited to the shown and disclosed embodiments, but other elements, improvements and variations are also within the scope of the invention. For example, it is clear for those skilled in the art that functions of the comparator 40 and the accumulator 23 can also be realized by loading the value of kₙₒₘ to a register, and subtracting the value of m from the register, while monitoring when the register reaches zero, instead of accumulating the m values. Also, the disclosed controlling functions of the various circuits may be realized in a number of different ways, either by hardware or software, though the preferred realization is with hardware.

1. A method for determining a calibration parameter, the calibration parameter being used to compensate the variations of a low accuracy clock signal compared to a high accuracy clock signal, the method comprising the steps of:
counting the number of cycles of said high accuracy clock signal during a single cycle of the low accuracy clock signal to obtain a first number representing the number of cycles counted;
performing successive summing operations with the first number until a sum of the first numbers reaches a first predetermined value; and
counting the number of summing operations required to reach the first predetermined value in order to determine the calibration parameter, where the calibration factor is proportional to the number of summing operations.

2. The method of claim 1, in which said first predetermined value is a ratio between the frequency of the high accuracy clock and a nominal value of a sleep mode frequency.

3. The method of claim 3, in which the calibration parameter is equal to the number of summing operations.

4. The method of claim 1, in which the summing operation is an addition, where the first number is initially added to a zero.

5. The method of claim 1, in which the summing operation is a subtraction, where the first number is successively subtracted from the first predetermined value, until the resulting number reaches a second predetermined value.

6. The method of claim 5, in which said first predetermined value is a ratio between the frequency of the high accuracy clock and a nominal value of a sleep mode frequency, and the second predetermined value is zero.

7. A circuit assembly for providing a calibrated clock signal in a sleep mode, using a high accuracy clock and a low accuracy clock which is periodically calibrated to the high accuracy clock when the high accuracy clock is in an active mode, the circuit comprising:
a high accuracy clock source;
a low accuracy clock source;
a calibration circuit or providing a calibration parameter, where the calibration parameter is used to compensate the variations of the frequency of the low accuracy clock signal compared a high accuracy clock signal;
a frequency calibration circuit for providing a calibrated clock signal from the low accuracy clock signal and the calibration parameter; and
where the calibration circuit comprises:
a first register for counting the number of clock cycles of the high accuracy clock during a clock cycle of the low accuracy clock, and for obtaining a first number,
an accumulator for performing successive summing operations of the first number obtained from the first register,
a second register for counting the number of summing operations performed by the second register and obtaining a second number, and
a control circuit configured to control the counting operations of the first and second registers, and the summing operations of the accumulator, monitor the contents of the accumulator and indicating when the content of the accumulator reaches a predetermined value, and output the second number from the second register as the calibration parameter when the content of said accumulator reaches said predetermined value.

8. The circuit assembly of claim 7, in which the frequency calibration circuit further comprises a frequency divider for dividing the frequency of the low accuracy clock with the calibration parameter.

9. The circuit assembly of claim 7, further comprising a third register for temporarily storing an actual value of the calibration parameter.

10. The circuit assembly of claim 9, in which said third register stores said value of the calibration parameter between calibration procedures initiated by a second control circuit.

11. The circuit assembly of claim 10, in which said second control circuit periodically initiates a calibration procedure of the low accuracy clock signal.

12. The circuit assembly of claim 7, the circuit assembly further including a comparator for comparing the content of said accumulator with said predetermined value.

13. The circuit assembly of claim 12, in which said predetermined value is hardwired into the comparator.

14. The circuit assembly of claim 12, in which said predetermined value is fed to an input of the comparator from a circuit external to the comparator.

15. The circuit assembly of claim 7, in which functions of said control circuit are hardware implemented.

16. The circuit assembly of claim 15, in which said functions of said control circuit comprise the resetting, enabling and halting of the controlled circuits, and detecting predetermined states of the controlled circuits.

17. A circuit for determining a calibration parameter, the calibration parameter being used to compensate the variations of a low accuracy clock signal compared to a high accuracy clock signal, the circuit comprising:
means for counting the number of cycles of said high accuracy clock signal during a single cycle of the low accuracy clock signal to obtain a first number representing the number of cycles counted;
means for performing successive summing operations with the first number until a sum of the first numbers reaches a first predetermined value; and
means for counting the number of summing operations required to reach the first predetermined value in order to determine the calibration parameter, where the calibration factor is proportional to the number of summing operations.

18. The circuit of claim 17, wherein the means for performing successive summing operations includes addition means for initially adding the first number to a zero value.

19. The circuit of claim 17, wherein the means for performing successive summing operations further comprises subtraction means for successively subtracting the first number from the first predetermined value to produce a resulting number until the resulting number reaches a second predetermined value.
